(19) United States
(12) Patent Application Publication
(10) Pub. No.: US 2007/0023781 A1
(43) Pub. Date: Feb. 1, 2007

(54) Semiconductor rectifier

(75) Inventors: Makoto Mizukami, Kawasaki-Shi (JP); Takashi Shinohe, Yokosuka-Shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/493,832

(22) Filed: Jul. 27, 2006

(30) Foreign Application Priority Data
Jul. 28, 2005 (JP) 2005-219450

(51) Int. Cl. H01L 31/00

(52) U.S. Cl. 257/192

(57) ABSTRACT

A semiconductor rectifier has a semiconductor layer formed on a substrate, an electric field reduced layer of conductive type contrary to that of the semiconductor layer, which is formed on the semiconductor layer positioned on a bottom portion of a trench formed on a portion of the semiconductor layer, a first electrode connected on the semiconductor layer adjacent to the trench by Schottky junction, a second electrode which is connected on sidewalls of the trench by Schottky junction, electrically conductive with the first electrode and made of a material different from that of the first electrode, and a third electrode formed on the substrate at opposite side of the semiconductor layer.

### CROSS REFERENCE TO RELATED APPLICATIONS

This application is based upon and claims the benefit of priority from the prior Japanese Patent Application No. 2005-219450, filed on Jul. 28, 2005, the entire contents of which are incorporated herein by reference.

### BACKGROUND OF THE INVENTION

1. Field of the Invention

The present invention relates to a semiconductor rectifier with a rectifying function.

2. Related Art

A Schottky barrier diode is a device for rectifying operation by using of a Schottky barrier formed on an interface between a semiconductor and metal. The interface is called as a Schottky junction surface. In the Schottky barrier diode, a rising voltage in forward direction, i.e. a threshold voltage, is determined based on a barrier height depending on a material of a semiconductor and the kind of a metal.

For example, if the barrier height of the interface is 1.2 eV when a metal electrode contacts a semiconductor made of an n-type 4H—SiC, the threshold voltage becomes 0.9 V.

If the n-type 4H—SiC is 5×10¹⁵ cm⁻³ in impurity concentration and is 10 μm in thickness, a withstand voltage becomes 1200 V. A withstand voltage is prescribed by a leak current of 6 mA/cm². It is desirable that the threshold voltage is as close to zero volts as possible because little current flows unless a voltage exceeding the threshold voltage is applied to the Schottky barrier diode. If the metal electrode with a barrier height of 0.9 eV contacts the above n-type 4H—SiC, the threshold voltage can be lowered to 0.6 V, but the withstand voltage deteriorates to 600 V.

Under such a background, a structure called “Junction Barrier Schottky” (]BS) has been proposed for the purpose of lowering the threshold voltage as well as suppressing reduction in withstand voltage, refer to “A Dual-Metal-Trench Schottky Pinch-Rectifier in 4H—SiC,” K. J. Schoen et al., IEEE ELECTRON DEVICE LETTERS, Vol. 19, No. 4, April 1998. In the structure disclosed in this document, a plurality of trenches are formed on a Schottky junction surface, a metal electrode with a low barrier height, such as Ti are formed on a semiconductor layer between trenches, and a metal electrode with a high barrier height, such as Ni are formed on a bottom and sidewalls of trenches. If a forward bias is applied to a diode with this structure, the threshold voltage is lowered by Ti electrode. If a reverse bias is applied to the diode, a depletion layer extends from the Ni electrode toward inside of the semiconductor layer, thereby reducing an electric field applied to the Ti electrode.

However, when the forward bias is applied, electric current flows selectively from the Ti electrode with low barrier height, producing a dead space in the Ni electrode portion, which increases on-resistance. On the other hand, when the reverse bias is applied, the electric field concentrates at the Ni electrode, thereby lowering the withstand voltage more than an electric field reduced layer with a pn junction like a general JBS structure.

The present invention is to provide a semiconductor rectifier capable of improving the withstand voltage by reducing an electric filed on the Schottky junction surface as well as decreasing on-resistance when the forward bias is applied.

### SUMMARY OF THE INVENTION

According to one embodiment of the present invention, a semiconductor rectifier comprising:

a semiconductor layer formed on a substrate, a trench being formed on a portion of the semiconductor layer;

an electric field reduced layer of conductive type contrary to that of the semiconductor layer, which is positioned on a bottom portion of the trench;

a first electrode connected on the semiconductor layer adjacent to the trench by Schottky junction;

a second electrode which is connected on sidewalls of the trench by Schottky junction, electrically conductive with the first electrode and made of a material different from that of the first electrode; and

a third electrode formed on the opposite side of the substrate from the semiconductor layer,

wherein a difference between a barrier height of the first electrode and a barrier height of the second electrode is smaller than a difference between the barrier height of the first electrode and the barrier height of the second electrode in a case where it is assumed that the first electrode and the second electrode are made of the same material.

According to one embodiment of the present invention, a method of manufacturing a semiconductor rectifier comprising:

forming a semiconductor layer on a substrate;

forming a trench on a portion of the semiconductor layer;

forming an electric field reduced layer of conductive type contrary to that of the semiconductor layer positioned on a bottom portion of the trench;

forming a first electrode connected on the semiconductor layer adjacent to the trench by Schottky junction; and

forming a second electrode which is connected on sidewalls of the trench by Schottky junction, conductive with the first electrode and made of a material different from that of the first electrode; and

forming a third electrode on the opposite side of the substrate from the semiconductor layer.

### BRIEF DESCRIPTION OF THE DRAWINGS

FIG. 1 is a cross section of a semiconductor rectifier according to a first embodiment of the present invention;

FIGS. 2A-2C are process charts showing an example of manufacturing process of the present embodiment;

FIGS. 3A-3C are process charts following FIG. 2;

FIGS. 4A-4C are process charts following FIG. 3;

FIG. 5 shows a relationship between work function and barrier height of metal in case where metals are arranged on the Si and C surfaces respectively;

FIG. 6 shows the variation of barrier height with manufacturing methods;

FIG. 7 shows the variation of barrier height with pre-processing methods used before metal is formed on the upper surface of the drift region 8;

FIG. 8 shows a cross section of a semiconductor rectifier according to a fourth embodiment of the present invention;

FIG. 9 shows a band gap at the interface between the electric field reduced layer 4a of the p-type polysilicon and the n-type SiC epitaxial layer 2 contacting the lower surface of the layer 4a, FIG. 9A a band gap in a thermal equilibrium state, FIG. 9B a band gap in applying forward bias and FIG. 9C a band gap in applying reverse bias;

FIGS. 10A-10C show the production processes of a semiconductor rectifier related to a fourth embodiment;

FIGS. 11A-11C show the production process charts following FIG. 10;

FIGS. 12A-12C show the production process charts following FIG. 11;

FIG. 13 shows a cross section of an example where a contacting surface between a second Schottky electrode 6 and the electric field reduced layer 4 is made ohmic contact 21;

FIG. 14 shows a cross section of a semiconductor rectifier provided with the n-type SiC epitaxial layer 2 with a first to third regions 22 to 24 different in impurity concentration from one another; and

FIG. 15 shows a cross section of a semiconductor rectifier related to a third modification where the outer region 4b of the electric field reduced layer 4 is made lower in impurity concentration than the inner region 4c.

### DETAILED DESCRIPTION OF THE INVENTION

One embodiment of the present invention is described below with reference to the drawings.

### First Embodiment

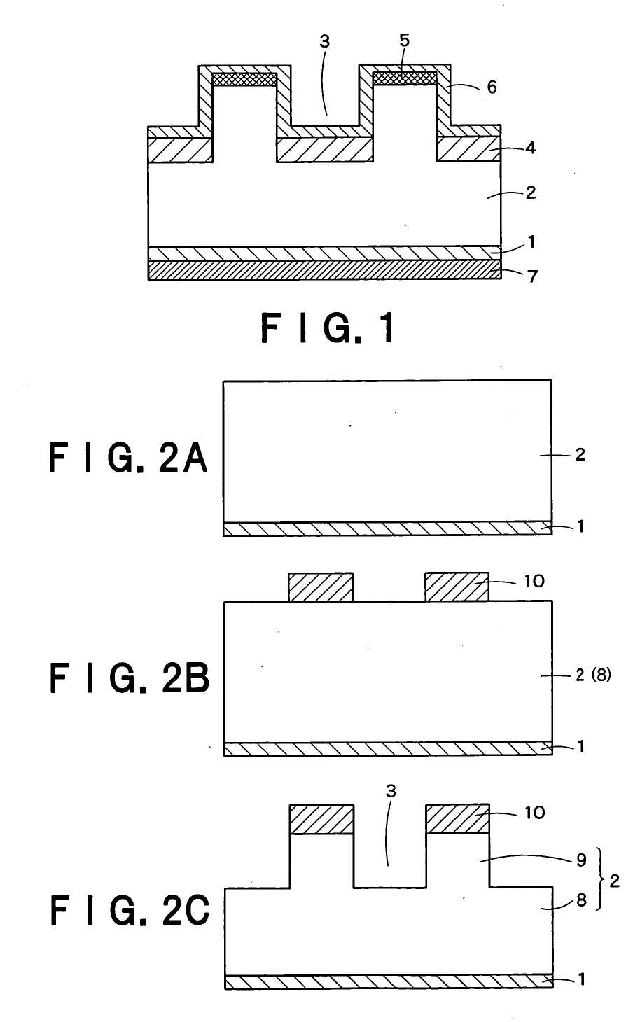

FIG. 1 is a cross section view of a semiconductor rectifier according to a first embodiment of the present invention. The semiconductor rectifier shown in FIG. 1 is provided with an n-type SiC epitaxial layer 2 formed on an n-type SiC substrate 1, trenches 3 separated from each other and formed at plural positions on the SiC epitaxial layer 2, a p-type electric field reduced layer 4 formed on the SiC epitaxial layer 2 positioned under the bottom of each trench 3, a first Schottky electrode 5 (a fist electrode) connected to a top surface of the SiC epitaxial layer 2 between the adjacent trenches 3 through a Schottky junction, a second Schottky electrode 6 (second electrodes) connected to the sidewalls of the trenches 3 through a Schottky junction, and a cathode electrode 7 (a third electrode) formed on the other side of the SiC substrate 1. The first Schottky electrode 5 is electrically conductive with the second Schottky electrode 6, which forms an anode electrode.

One of the characteristics of the present embodiment, i.e. a first characteristic, is that a difference between a barrier height of the first Schottky electrode 5 and a barrier height of the second Schottky electrode 6 is set smaller than the difference between the barrier heights of the electrodes formed from the same material and by the same manufacturing method. Therefore, it is possible to reduce on-resistance at the forward bias time, and to easily flow electric current from the anode electrode into the cathode electrode 7.

The top surface of the SiC epitaxial layer 2 between the adjacent trenches 3 is different in surface orientation from the sidewall portion of the trenches 3. The difference in surface orientation causes a difference in work function. Therefore, even if the same electrode, more specifically, a film-shaped electrode formed from the same material and by the same manufacturing method, is formed thereon, both barrier heights are different from each other. In this case, electric current at a portion with high barrier height flows less than a portion with low barrier height. As a result, the anode electrode has a portion where electric current does not flow so much, thereby increasing the on-resistance.

Thus, in the present embodiment, the electrodes are formed on the top surface of the SIC epitaxial layer 2 between the trenches 3 and on the sidewall of the trenches 3 so that the difference becomes smaller than the difference in the case of forming the electrode made of the same material and the same manufacturing method.

Therefore, a region where electric current does not flow so much in the anode electrode decreases, thereby reducing the on-resistance.

Other characteristic of the present embodiment, i.e. a second characteristic, is that the p-type electric field reduced layer 4 is provided at the bottom of the trench 3 to contact the electric field reduced layer 4 with the anode electrode. When the forward bias is applied, internal barrier of the interface between the electric field reduced layer 4 and the anode electrode becomes low, thereby flowing electron current from the electric field reduced layer 4. When a reverse bias is applied, a depletion layer is formed by pn junction between the electric field reduced layer 4 and the SiC epitaxial layer 2 which contacts the SiC epitaxial layer 2, thereby reducing the electric field at Schottky junction portion. Therefore, it is possible to reduce a leak current at the sidewall portion and the bottom portion of the trenches 3.

FIGS. 2 to 4 are process charts showing an example of manufacturing process of the present embodiment. The manufacturing process of the semiconductor rectifier according to the present embodiment will be described below based upon these drawings. First, an n-type SiC substrate 1 with a lower resistance is prepared, on which an n-type SiC epitaxial layer 2 including an impurity concentration of 1×10¹⁶ cm⁻³ is grown by 10 μm as a drift region 8 (FIG. 2A).

The concentration and thickness of the drift region 8 depend on the performances of a targeted device. When a withstand voltage is determined by avalanche, and when a unipolar element of 4H—SiC with crystal orientation (0001) of Si surface and crystal orientation (000-1) of C surface is fabricated for example, a relationship between a targeted withstand voltage V (V) and an optimum concentration N cm⁻³ of the drift region 8 is represented by N=1.70×10²⁰×v^{-1.303}. A relationship between the targeted withstand voltage V and an optimum thickness W cm of the drift region 8 is expressed by W=1.94×10⁻⁷×v^{1.1517}.

On the other hand, when a unipolar element of 6H—SiC with crystal orientation (0001) of Si surface and crystal orientation (000-1) of C surface is fabricated, a relationship between the targeted withstand voltage V and the optimum concentration N of the drift region 8 is represented by N=2.62×10²⁰×v^{-1.323}. A relationship between the targeted withstand voltage V and the optimum thickness W of the drift region 8 is expressed by W=1.57×10⁻⁷×v^{1.1617}.

The 4H and the 6H express the shape of SiC single crystal, the 4H is four-cycle hexagonal and the 6H is six-cycle hexagonal.

If a targeted withstand voltage is for example 1200 V, the drift region 8 is 6.8 μm in thickness and the impurity concentration is 1.7×10¹⁶ cm⁻³.

In general, the thickness of the drift region 8 is optimized within ±50% of the thickness of the optimum drift region 8, or more preferably within ±20% in order to improve yield, the forward and the reverse characteristics of the element for attaining a targeted withstand voltage. When the withstand voltage is determined by leak current, the drift region 8 is made thicker than the optimum value at avalanche or the impurity concentration is lowered.

The drift region 8 extends from the bottom of the n-type SiC epitaxial layer 2 to the main junction. In the present embodiment, the drift region 8 extends from the bottom of the n-type SiC epitaxial layer 2 to the electric field reduced layer 4. The upper part disposed above the electric field reduced layer 4, or the SiC epitaxial layer 2 between the adjacent trenches 3 is a channel region 9. The combination of the drift and channel regions 8 and 9 corresponds to the SiC epitaxial layer 2.

The SiC substrate 1 serves as a contact region of the cathode electrode 7 at the other surface side. The n-type SiC epitaxial layer 2 is formed on the SiC substrate 1, and thereafter organic dirt stuck to the SiC substrate 1 and the n-type SiC epitaxial layer 2 is removed by mixed acid of sulfuric acid and hydrogen peroxide water and washed in pure water. Subsequently, metallic impurities stuck to the SiC substrate 1 and the n-type SiC epitaxial layer 2 is removed by mixed acid of dilute hydrochloric acid and hydrogen peroxide water, and then is washed in pure water. Furthermore, natural oxide film on the surface of the SiC substrate 1 and the n-type SiC epitaxial layer 2 is removed by dilute hydrofluoric acid and washed in pure water.

After that, the SiC substrate 1 and the n-type SiC epitaxial layer 2 are heated for five minutes to four hours at a temperature of 900° C. to 1200° C. under an oxygen atmosphere to oxidize the surface of the n-type SiC epitaxial layer 2, forming a sacrificial oxide film. In this case, heating is conducted for two hours at a temperature of 1100° C., for example. This sacrificial oxide film is used to improve adhesion with oxide film formed at the following process as an ion implanting mask.

Subsequently, a metallic film with terminating structure is formed as an ion implanting mask on the upper surface of the abovementioned sacrificial oxide film. Subsequently, resist is coated on the upper surface of the metallic film and patterned by photolithography technique to form a resist pattern having openings at regions corresponding to a resurf and a guard-ring regions functioning as terminated structure. Thereafter, the metallic film is patterned using the formed resist pattern as a mask to form a metallic mask used as an ion implanting mask.

Subsequently, aluminum ions are implanted in multiple stages using the metallic film as a mask with a total dose of 1.0×10¹² cm⁻² to 1.0×10¹⁵ cm⁻² and a maximum acceleration energy of 50 keV to 500 keV to form the resurf and the guard-ring regions (not shown). In the present embodiment, the resurf and the guard-ring regions are formed with a total dose of 1.5×10¹³ cm⁻² and a maximum acceleration energy of 300 eV.

After that, organic substance such as resist stuck to the surface of the substrate and ion implanting mask are removed by mixed acid of sulfuric acid and hydrogen peroxide water, and then washed in pure water.

Subsequently, a mask is formed for forming trenches 3 on the upper surface of the substrate. An oxide film is formed to be used as a mask for forming the trenches and for implanting ions on the electric field reduced layer on the foregoing upper surface of sacrificial oxide film. Subsequently, a resist is coated on the upper surface of the oxide film and patterned by photolithography technique to form a resist pattern having openings at the regions for forming the trenches and for implanting ions on the electric field reduced layer. Thereafter, the oxide film is patterned by using the formed resist as a mask to form the oxide film 10 used as a mask for implanting ions (FIG. 2B).

The mask has openings corresponding to regions for forming the trenches 3. Subsequently, the trenches 3 are formed at a portion of the SiC epitaxial layer 2 with RIE by using the mask (FIG. 2C). Etching gas used in RIE is mixed gas of for example CF₄ and O₂, but not limited to a specific type of gas. The mask for forming the trench 3 needs to be made of a material capable of blocking ion implantation and be thick because it is also used as a mask for implanting ions at the following process.

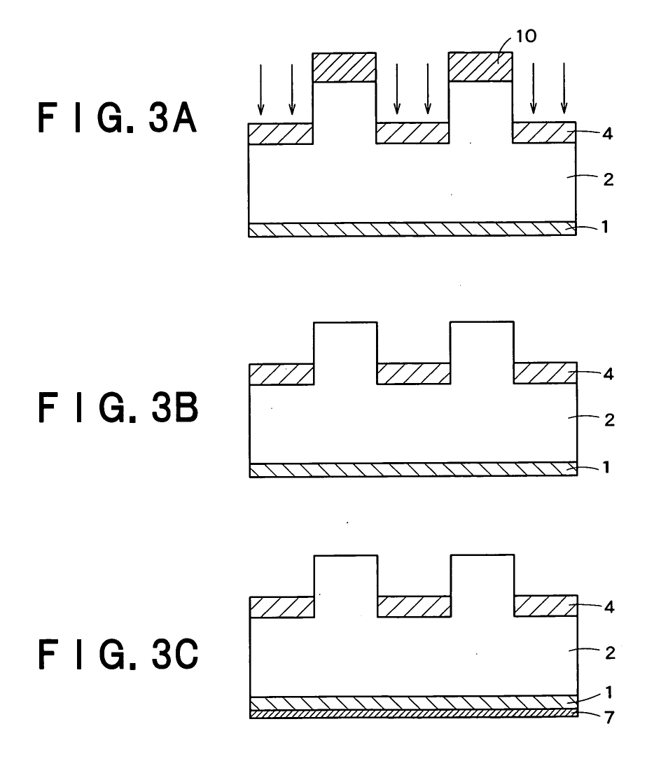

Then, ions of at least one of boron or aluminum are implanted with a mask for forming the trench 3 in the region where the electric field reduced layer 4 is formed (FIG. 3A). The implanting region is about 0.6 μm in thickness with a concentration of 1×10¹⁸ cm⁻³ for instance.

The mask and the sacrificial oxide film on the surface of the substrate are removed by dilute hydrofluoric acid. The substrate is then washed in mixed acid of sulfuric acid and hydrogen peroxide water and washed in pure water, thereafter minor metal contaminants are removed by mixed acid of hydrochloric acid and hydrogen peroxide water and the substrate is again washed in pure water. Finally, the oxide film on the surface of the substrate oxidized by acid in washing is removed by dilute hydrofluoric acid, thereafter sufficiently washed in pure water.

Subsequently, the washed substrate is introduced into an induction heating heat treatment device, from which air is evacuated and replaced with argon, thereafter, the substrate is heated at a temperature of up to 1600° C. for example to activate the implanted ions, thereby forming the electric field reduced layer 4 (FIG. 3B).

Then, the Ni film is formed on the other side of the substrate, and then it is sintered under atmosphere of argon at a temperature of 1000° C. for five minutes to form the cathode electrode 7 (FIG. 3C).

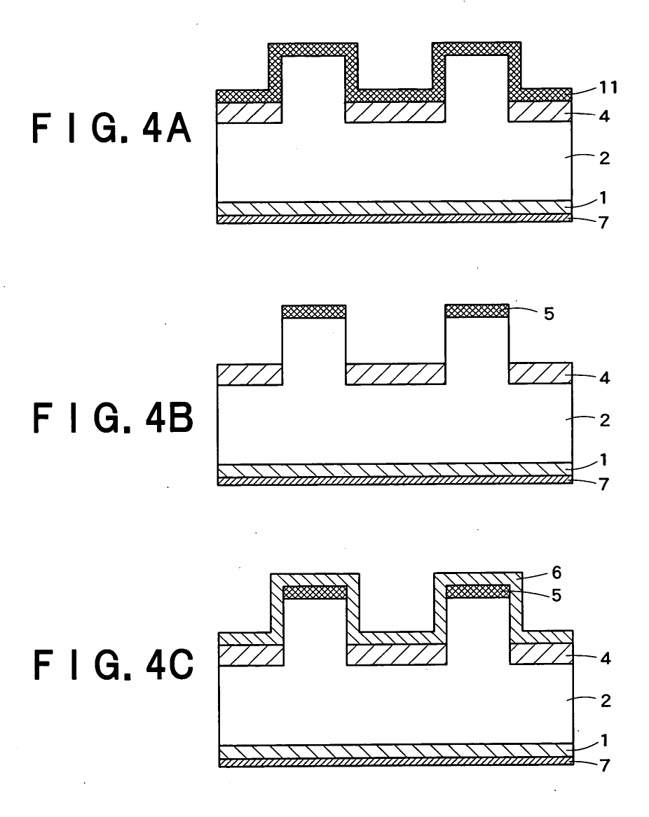

A material 11 for the first Schottky electrode 5 is formed on the substrate (FIG. 4A) and patterned to form the first Schottky electrode 5 on the upper surface of the SiC epitaxial layer 2 between the trenches 3 (FIG. 4B). A detailed method of patterning is not concerned, but for example, a general dry etching such as RIE or the like, or a wet etching using acid, alkali, or the like may be used.

A material for the second Schottky electrode 6 is formed on the substrate (FIG. 4C). Therefore, a Schottky junction by the first Schottky electrode 5 and the SiC epitaxial layer 2 is formed on the surface of the SiC epitaxial layer 2 between the trenches 3, and a Schottky junction by the second Schottky electrode 6 and the SiC epitaxial layer 2 is formed on the sidewalls of the trenches 3. The second Schottky electrode 6 is connected to the electric field reduced layer 4 at the bottom portion of the trenches 3.

As a material for the first and the second Schottky electrodes 5 and 6, it is assumed to use any one of metals selected from Ti, Ni, Mo, W, Co, Pt, Pd, Zr or Hf, or Si compound of the selected metal, or Au, or alloy of the selected metal.

In the drift region 8 consisting of the n-type SiC epitaxial layer 2, almost all of atoms arranged at the anode electrode side are either Si atoms (hereinafter referred to as “Si surface”) or C atoms (hereinafter referred to as “C surface”). If the drift region 8 is formed from the same material and by the same manufacturing method, the metal arranged on the Si surface is lower in barrier height than the metal arranged on the C surface.

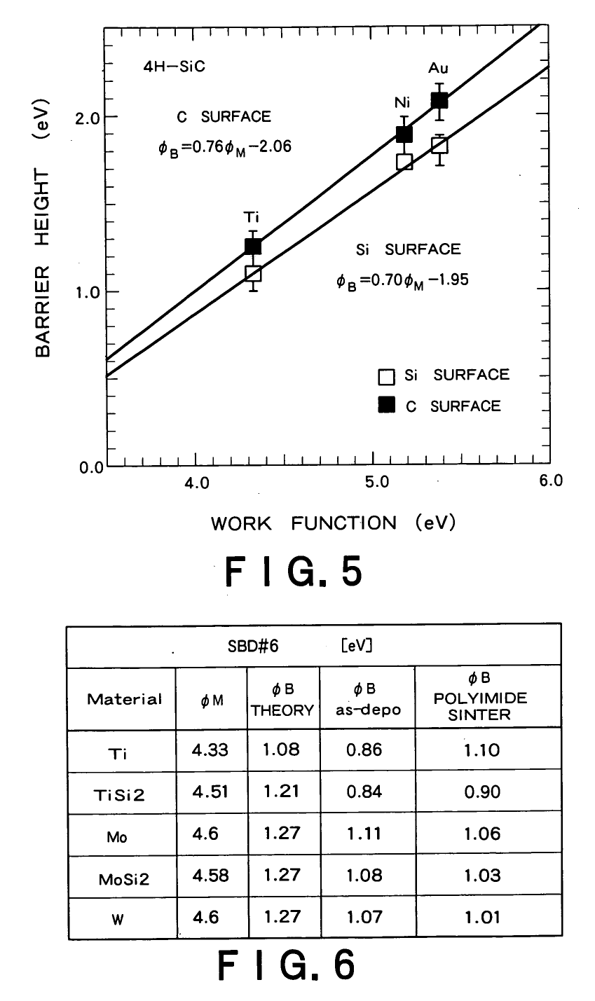

FIG. 5 shows a relationship between work function and barrier height of metal in case where the metal is arranged on the Si and the C surface respectively. As shown in the figure, it can be seen that the metal arranged on the Si surface is lower in barrier height than that arranged on the C surface.

FIG. 6 shows the variation of barrier height with manufacturing methods. In FIG. 6, a reference character φM denotes work function of metal itself, φB denotes theoretical barrier height on the 4H—SiC surface, φBas-depo denotes barrier height at a state where a film of metal is only formed on the 4H—SiC, and φB polyimide sinter denotes barrier height at a state where metal is formed and then heat-treated. As shown in FIG. 6, it can be seen that barrier height is changed by heat treatment.

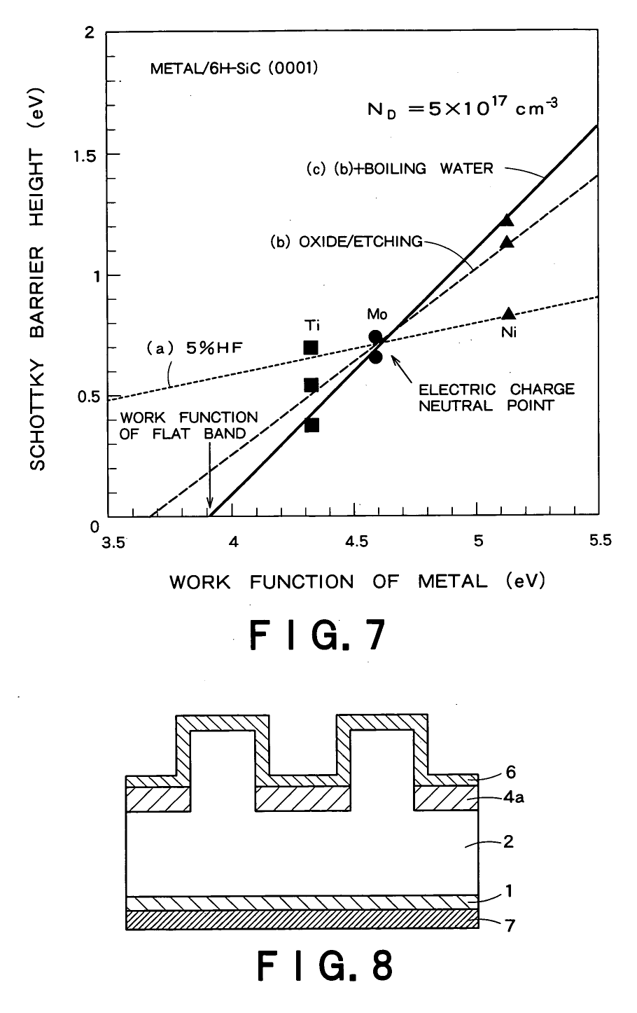

FIG. 7 shows the variation of barrier height with pre-processing methods used before metal is formed on the upper surface of the drift region 8. A straight line (a) in FIG. 7 shows the variation of barrier height in a case where natural oxide film is removed by dilute hydrofluoric acid, a straight line (b) shows the variation of barrier height in a case where a surface thermal oxidation and an oxide film etching are performed, and a straight line (c) shows the variation of barrier height in a case where boiling water is used in addition to the conditions of the straight line (b).

As can be seen from FIG. 7, barrier height is significantly influenced by the extent of surface dirt of the SiC epitaxial layer 2.

The present embodiment decreases the difference between the barrier height of the first Schottky electrode 5 formed on the SiC epitaxial layer 2 between the trenches 3 and the barrier height of the second Schottky electrode 6 formed on the sidewalls of the trenches 3 as much as possible. More specifically, the difference in this case is made smaller than that between the barrier heights of the first and the second Schottky electrodes 5 and 6 which are made of the same material and formed by the same manufacturing method. This can be realized by making the material or manufacturing method of the first Schottky electrode 5 different from those of the second Schottky electrode 6 as shown in FIGS. 6 and 7. The following is a description of an example where the kinds of the first and the second Schottky electrodes 5 and 6 are changed for the purpose of reducing the difference between the barrier heights.

As shown in FIG. 5, a barrier height is changed depending on whether almost all of either Si or C atoms are arranged at the anode electrode side in the n-type SiC epitaxial layer 2. For this reason, the kinds of the first and the second Schottky electrodes 5 and 6 need changing according to the arrangement of the Si and the C atoms.

More specifically, when the upper surface of the SiC epitaxial layer 2 between the adjacent trenches 3 is the SiC surface, even if the first and the second Schottky electrodes 5 and 6 are formed by using the same material and by the same manufacturing method, the barrier height of the first Schottky electrode 5 becomes lower than that across the second Schottky electrode 6. Therefore, in this case, a material larger in work function than a material used for the second Schottky electrode 6 is selected as a material used for the first Schottky electrode 5, thereby reducing the difference between both the electrodes.

On the contrary, when the upper surface of the SiC epitaxial layer 2 between the adjacent trenches 3 is the C surface, even if the first and the second Schottky electrodes 5 and 6 are formed by using the same material and by the same manufacturing method, the barrier height of the first Schottky electrode 5 becomes higher than that of the second Schottky electrode 6. Therefore, in this case, a material smaller in work function than a material used for the second Schottky electrode 6 is selected as a material for the first Schottky electrode.

As a simplified method, if the Si and the C atoms are reversely arranged to each other in the SiC epitaxial layer 2, the materials of the first and the second Schottky electrodes 5 and 6 may be replaced with each other.

Thus, in the first embodiment, the difference between the barrier height of the first Schottky electrode 5 formed on the SiC epitaxial layer 2 between the adjacent trenches 3 and the barrier height of the second Schottky electrode 6 formed on the sidewalls of the trenches 3 is made smaller than the difference between the barrier heights in the case of forming by using the same material and by the same manufacturing method, thereby reducing the on-resistance. Further, because the electric field reduced layer 4 is provided on the bottom portion of the trenches 3, the depletion layer extends at a time of reverse bias, thereby reducing the leak current at the bottom and the sidewalls of the trench 3.

### Second Embodiment

In the first embodiment, an example has been described in which the material of the first Schottky electrode 5 is different from that of the second Schottky electrode 6 to decrease the difference of the barrier heights. In the second embodiment described below, the difference between barrier heights is reduced by changing manufacturing method. More specifically, the difference between barrier heights of both the electrodes is reduced by controlling at least one of the heat treatment condition in which the first Schottky electrode 5 is formed and that in which the second Schottky electrode 6 is formed.

In general, it has been known that the barrier height φB varies with a heat treatment temperature even if the electrodes are formed from the same material. This is because temperature causes diffusion and reaction to proceed to change the barrier height φB determined at the interface of metal/SiC. For example, nickel (Ni) is 1.7 eV in barrier height φB on the Si surface at room temperature, but, barrier height φB on the Si surface is 1.45 eV to 1.5 eV when reacted at a temperature of 400° C.

When silicide such as TiSi₂, WSi₂, MoSi₂, NiSi₂, CoSi₂, PtSi, Pd₂Si and Ir₃Si is selected as a material, on the other hand, barrier height is little changed at temperatures from room temperature to 1500° C. in a general semiconductor manufacturing process. The reason is that when a metal by itself contacts the SiC interface, the barrier height changes to form silicide or carbide, and on the other hand, when a thermally stable silicide initially contacts the SiC interface, the metal does not react to SiC even if temperature rises.

Specifically, the relationship between barrier height φB and heat treatment temperature is known only at Ti, Mo and W, and TiSi₂, MoSi₂, and Ni. When Ti is formed on the upper surface of the SiC epitaxial layer 2 between the adjacent trenches 3 and Mo is formed on the sidewalls of the trenches 3 to react them at a temperature of 300° C., both are 1.1 eV in barrier height.

On the other hand, when Mo is formed on the upper surface of the SiC epitaxial layer 2 between the adjacent trenches 3 and Ti is formed on the sidewalls of the trenches 3 to react them at a temperature of 500° C., both are also 1.1 eV in barrier height, which substantially corresponds with each other.

Thus, by changing heat treatment temperature at the time of forming the first and the second Schottky electrodes 5 and 6, it is possible to control the difference between barrier heights of the first and the second Schottky electrodes 5 and 6. It is possible to lower the on-resistance by controlling heat treatment temperature when forming at least one of the first Schottky electrode 5 and the second Schottky electrode 6.

### Third Embodiment

In the third embodiment, the dose amount of the impurity ions in the n-type SiC epitaxial layer 2 is changed to change the difference between the barrier heights of the first Schottky electrode 5 and the second Schottky electrode 6.

It has been generally known that the barrier height φB varies according to the thickness of diffusion layer in a semiconductor (refer to Japanese Patent Laid-Open Pub. No. 2002-299643). For example, if an impurity concentration per unit volume is 1×10¹⁹ cm⁻³, and if a p-type semiconductor layer is 2 nm in thickness, the dose amount will be 2 nm×10¹⁹ cm⁻³, and φB is equal to 1.2 eV. If it is 6 nm in thickness, the dose will be 6 nm×10¹⁹ cm⁻³, and φB is equal to 1.6 eV. If it is 10 nm in thickness, the dose amount will be 10 nm×10¹⁹ cm⁻³, and φB is equal to 2.0 eV.

Accordingly, if at least one of the dose amount into the SiC epitaxial layer 2 which contacts the first Schottky electrode 5 and the dose amount into the SiC epitaxial layer 2 which contacts the second Schottky electrode 6 can regulate the difference between the barrier heights of the first and the second Schottky electrodes 5 and 6.

Thus, in the third embodiment, since at least one of the dose amount into the SiC epitaxial layer 2 which contacts the first Schottky electrode 5 and the dose amount into the SiC epitaxial layer 2 which contacts the second Schottky electrode 6 is controlled, even if the first and the second Schottky electrodes 5 and 6 are formed from the same material, the difference between the barrier heights of both electrodes can be reduced, which can lower the on-resistance as is the case with the first and second embodiments.

### Fourth Embodiment

In the fourth embodiment, the material for the electric field reduced layer 4 is changed to further weaken electric field at a time of the reverse bias and to further lower on-resistance at a time of the forward bias.

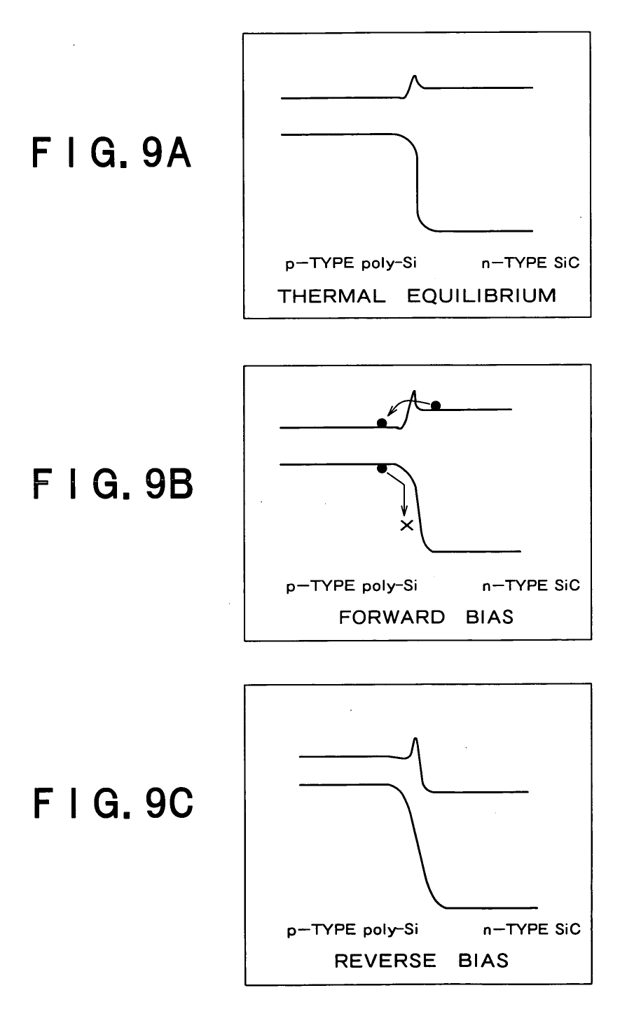

FIG. 8 is a cross section view of a semiconductor rectifier according to a fourth embodiment of the present invention. The electric field reduced layer 4a in FIG. 8 is formed of a p-type polysilicon. FIG. 9 is a view showing a band gap at the interface between the electric field reduced layer 4a made of the p-type polysilicon and the n-type SiC epitaxial layer 2 which contacts the lower surface of the layer 4a. FIG. 9A shows a band gap in a thermal equilibrium state, FIG. 9B a band gap in applying at a time of the forward bias, and FIG. 9C a band gap at a time of the reverse bias.

As shown in FIG. 9B, an internal barrier between the p-type polysilicon and the n-type SiC epitaxial layer 2 is lower at a time of the forward bias. Therefore, electrons easily move from the SiC epitaxial layer 2 to the p-type polysilicon. On the other hand, as shown in FIG. 9C, an internal barrier between the p-type polysilicon and the n-type SiC epitaxial layer 2 is higher at a time of the reverse bias. Therefore, a depletion layer extends along the pn junction surface, thereby preventing the electric field from concentrating at the anode electrode and further suppressing the leak current at the sidewalls and bottom of the trench 3.

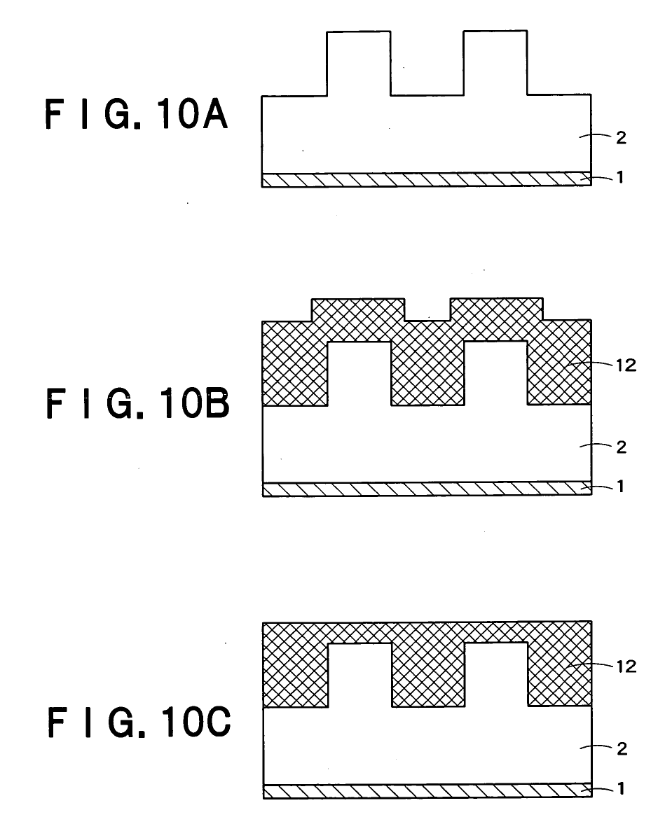

FIGS. 10 to 12 show manufacturing process charts of a semiconductor rectifier according to a fourth embodiment. The processes preceding the formation of the trenches 3 are the same as those of the aforementioned first embodiment, so that the process charts are omitted. First, the trenches 3 are formed in FIG. 10A, and then a polysilicon layer 12 including the inside of the trench 3 is formed on the substrate (FIG. 10B), and the surface of the substrate is flattened (FIG. 10C).

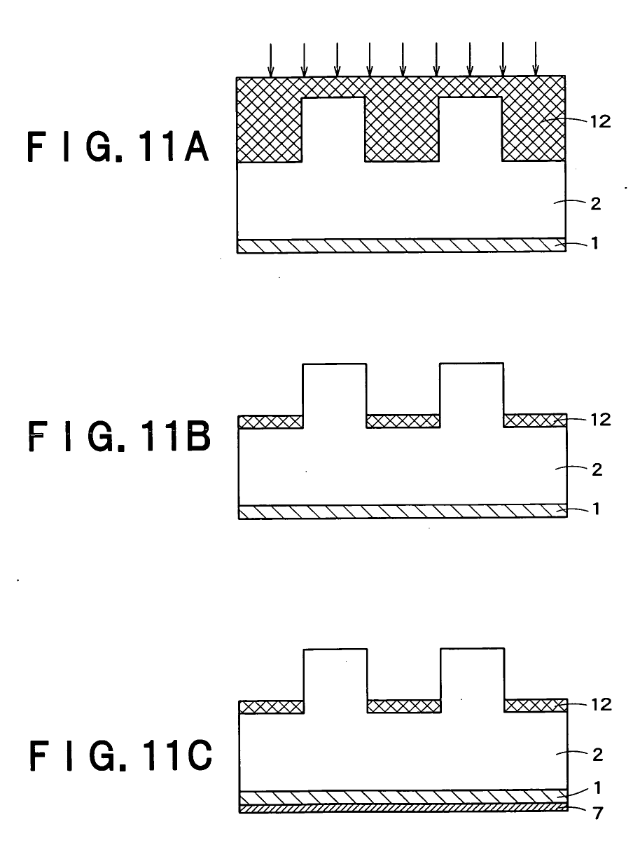

Subsequently, p-type impurity ions are implanted into the polysilicon layer 12, and then thermal diffusion is performed (FIG. 11A). After that, etchback is performed to remove the polysilicon layer in the trenches 3. At this point, the etchback is so performed as to leave the polysilicon layer 12 with a predetermined thickness at the bottom portion of the trench 3 (FIG. 11B). Thereafter, the cathode electrode 7 is formed on the other side of the SiC substrate 1 (FIG. 11C).

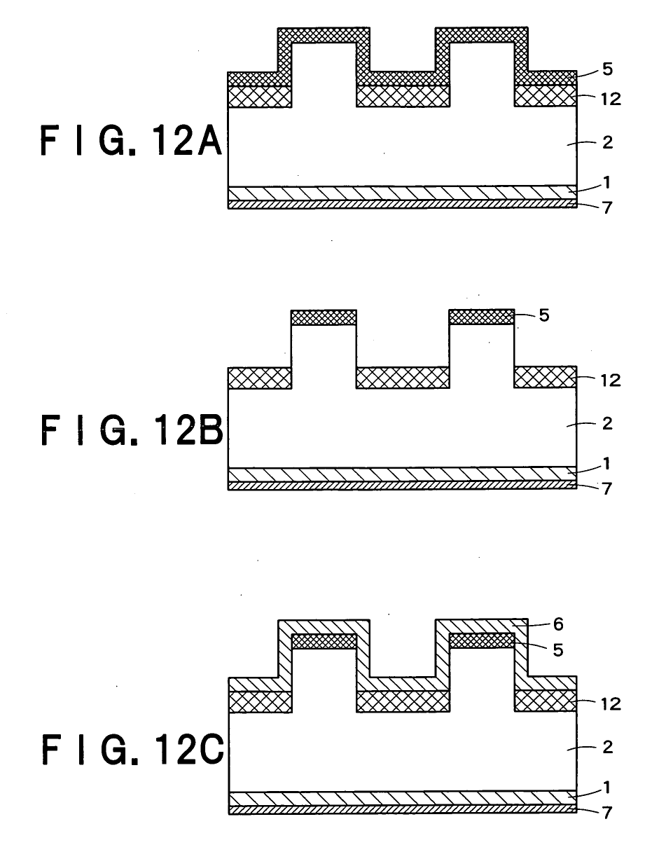

The succeeding processes are the same as in the first embodiment. The first Schottky electrode 5 is formed on the upper surface of the n-type SiC epitaxial layer 2 between the trenches 3 (FIGS. 12A and 12B) and then the second Schottky electrode 6 is formed on the entire upper surface of the substrate (FIG. 12C).

As described above, in the fourth embodiment, since the electric field reduced layer 4 is formed of p-type polysilicon, the on-resistance can be further reduced and the electric field can be further weakened when the reverse bias is applied.

### Other Embodiments

In the foregoing first to fourth embodiments, various modifications are possible if necessary. Some of these modifications will be described below.

(First Modification)

As shown in FIG. 1, the second Schottky electrode 6 contacts the electric field reduced layer 4. The contacted surface may be ohmic contact.

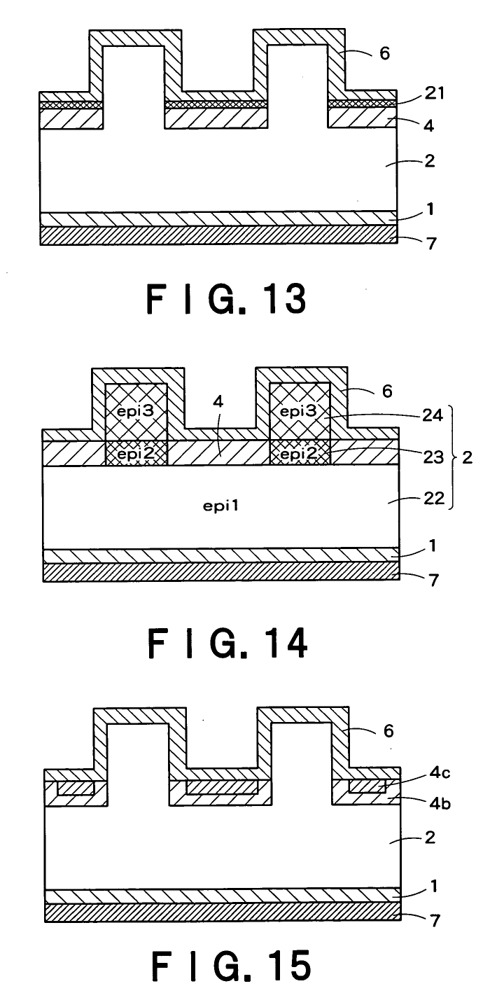

FIG. 13 is a cross section view of an example in which a contact surface between the second Schottky electrode 6 and the electric field reduced layer 4 has an ohmic contact 21. In this case, while the reverse bias is applied to the semiconductor rectifier shown in FIG. 1 to deplete the drift region 8, holes are discharged from the p-type electric field reduced region. Because the contact surface has the ohmic contact, discharging resistance of holes lowers, thereby operating the semiconductor rectifier stably and at high frequency The ohmic contact can be formed by forming an ohmic electrode which contacts the electric field reduced layer 4 before the first Schottky electrode 5 is formed.

(Second Modification)

On-resistance may be lowered by varying stepwise impurity concentration in the n-type SiC epitaxial layer 2. FIG. 14 is a cross section view of a semiconductor rectifier provided with the n-type SiC epitaxial layer 2 having a first to third regions 22 to 24 different in impurity concentration from one another. The first region set to be higher in impurity concentration than the second and third regions, thereby further reducing on-resistance.

(Third Modification)

FIG. 15 is a cross section view of a semiconductor rectifier according to a third modification in which the outer region 4b in the electric field reduced layer 4 is made lower in concentration than the inner region 4c. Since the outer region 4b is made lower in concentration, electric field can further concentrate at the corner portions of the trenches 3, avoiding degradation in withstand voltage.

For example, aluminum and boron ions are implanted into the inner region 4c and the outer region 4b in the electric field reduced layer 4 respectively and thermally diffused. Aluminum is lower in thermal diffusion coefficient than boron, so that only boron is thermally diffused. This permits thermally diffused boron to enclose defect caused by implanting ions, which enables suppressing the concentration of electric field at the defect part.

(Fourth Modification)

The above modifications describe examples where a plurality of the trenches are formed on the SiC epitaxial layer 2, but the number of trenches is not limited, or only one trench may be provided.

What is claimed is:

1. A semiconductor rectifier comprising:
a semiconductor layer formed on a substrate, a trench being formed on a portion of the semiconductor layer;
an electric field reduced layer of conductive type contrary to that of the semiconductor layer, which is positioned on a bottom portion of the trench;
a first electrode connected on the semiconductor layer adjacent to the trench by Schottky junction;
a second electrode which is connected on sidewalls of the trench by Schottky junction, electrically conductive with the first electrode and made of a material different from that of the first electrode; and
a third electrode formed on the opposite side of the substrate from the semiconductor layer,
wherein a difference between a barrier height of the first electrode and a barrier height of the second electrode is smaller than a difference between the barrier height of the first electrode and the barrier height of the second electrode in a case where it is assumed that the first electrode and the second electrode are made of the same material.

2. The semiconductor rectifier according to claim 1,
wherein the first electrode is one material selected from Ti, Ni, Mo, W, Co, Pt, Pd, Zr and Hf, or a Si compound of the selected material, or an Au compound of the selected material.

3. The semiconductor rectifier according to claim 1,
wherein the semiconductor layer is SiC.

4. The semiconductor rectifier according to claim 1,
wherein a surface of the semiconductor layer adjacent to the trench is a Si surface.

5. The semiconductor rectifier according to claim 1,
wherein a surface of the semiconductor layer adjacent to the trench is a C surface.

6. The semiconductor rectifier according to claim 1,
wherein the electric field reduced layer includes polysilicon.

7. The semiconductor rectifier according to claim 1,
wherein the second electrode is formed to overlap the sidewalls of the trench and the first electrode,
the difference being a difference between the barrier height of the first electrode and the barrier height of the second electrode positioned on the sidewalls of the trench.

8. The semiconductor rectifier according to claim 1,
wherein the semiconductor layer has:
a first diffusion region formed on a region in contact with the first electrode; and
a second diffusion region formed on a region in contact with the second electrode on the sidewalls of the trench, which has dose amount of impurity ions different from that of the first diffusion region.

9. The semiconductor rectifier according to claim 1,
wherein a contact surface between the electric field reduced layer and the second electrode has an ohmic contact.

10. The semiconductor rectifier according to claim 1,
wherein the semiconductor layer has a plurality of diffusion regions each having different concentration of impurity ions.

11. The semiconductor rectifier according to claim 1,
wherein the electric field reduced layer has:
an inner region in contact with the bottom portion of the trench; and
an outer region which has larger dose amount of the impurity ions than that of the inner region and overlaps surroundings of the inner region.

12. A method of manufacturing a semiconductor rectifier comprising:
forming a semiconductor layer on a substrate;
forming a trench on a portion of the semiconductor layer;
forming an electric field reduced layer of conductive type contrary to that of the semiconductor layer positioned on a bottom portion of the trench;
forming a first electrode connected on the semiconductor layer adjacent to the trench by Schottky junction; and
forming a second electrode which is connected on sidewalls of the trench by Schottky junction, conductive with the first electrode and made of a material different from that of the first electrode; and
forming a third electrode on the opposite side of the substrate from the semiconductor layer.

13. The method according to claim 12,
wherein heat treatment temperature in a case of forming the first electrode is different from that in a case of forming the second electrode.

14. The method according to claim 12,
wherein dose amount of impurity ions implanted in the semiconductor layer in contact with the first electrode is different from that of the semiconductor layer in contact with the second electrode.

15. The method according to claim 12,
wherein a difference between a barrier height of the first electrode and a barrier height of the second electrode is smaller than a difference between the barrier height of the first electrode and the barrier height of the second electrode in a case where it is assumed that the first electrode and the second electrode are made of the same material.

16. The method according to claim 12,
wherein the first electrode is one material selected from Ti, Ni, Mo, W, Co, Pt, Pd, Zr and Hf, or a Si compound of the selected material, or an Au compound of the selected material.

17. The method according to claim 12,
wherein the semiconductor layer is SiC.

18. The method according to claim 12,
wherein a surface of the semiconductor layer adjacent to the trench is a Si surface.

19. The method according to claim 12,
wherein a surface of the semiconductor layer adjacent to the trench is a C surface.

20. The method according to claim 12,
wherein the electric field reduced layer includes polysilicon.
